(19) United States
(12) Patent Application Publication
(10) Pub. No.: US 2010/0244204 A1
(43) Pub. Date: Sep. 30, 2010

(54) FILM FORMING METHOD, FILM FORMING APPARATUS, STORAGE MEDIUM AND SEMICONDUCTOR DEVICE

(75) Inventors: Takaaki Matsuoka, Tokyo (JP); Masahiro Horigome, Yamanashi (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/301,902

(22) PCT Filed: May 11, 2007
(86) PCT No.: PCT/JP2007/059775

§ 371 Date: Nov. 21, 2008

(30) Foreign Application Priority Data
May 25, 2006 (JP) 2006-145620

(51) Int. Cl. H01L 23/58; H01L 21/469

(52) U.S. Cl. 257/632; 438/778; 118/723 R; 118/723 AN; 118/696; 257/E23.001; 257/E21.487

(57) ABSTRACT

Provided is a technology capable of obtaining a fluorine-containing carbon film having a good leakage property, coefficient of thermal expansion and mechanical strength. The fluorine-containing carbon film is formed by using active species obtained by activating a C₅F₈ gas and a hydrogen gas. Fluorine in the fluorine-containing carbon film comes off together with H so that the amount of F decreases, thereby accelerating the polymerization. As a result, a C-dangling bond in the fluorine-containing carbon is decreased and a leakage current is reduced. Further, as the polymerization accelerates, the film gets stronger, so that the fluorine-containing carbon film having a high mechanical strength such as a high elasticity or a high hardness can be obtained.

### TECHNICAL FIELD

The present invention relates to a technology for forming a fluorine-containing carbon film by using plasma.

### BACKGROUND ART

To achieve high integration of a semiconductor device, a multilayer wiring structure has been employed. However, with the progression of miniaturization and high integration, a delay of an electric signal passing through a wiring (i.e., wiring delay) has been a problem which impedes a realization of a high speed operation of the device. Since the wiring delay is proportional to the product of a wiring resistance and an inter-wiring capacitance, it is required to lower a resistance of an electrode wiring material and a dielectric constant of an interlayer dielectric for insulating each layer in order to shorten the wiring delay. For this purpose, it has been considered to use copper (Cu) as the wiring material because it has a lower resistance than conventionally used aluminum (Al).

Further, though a porous film (SiCOH film) containing silicon, carbon, oxygen and hydrogen and having a dielectric constant of about 2.7 and a sufficient mechanical strength is gaining attention as the interlayer dielectric, the inventors of the present invention have considered using a fluorine-containing carbon film (fluorocarbon film) which is a compound of carbon (C) and fluorine (F) and has a dielectric constant lower than that of the SiCOH film.

The fluorine-containing carbon film is very useful film because a dielectric constant as low as, for example, about 2.5 or below can be obtained depending on a selection of a kind of a source gas. However, to be used as the interlayer dielectric, it needs to have a low leakage current, and it also needs to have a sufficient mechanical strength to endure an impact that might be applied thereto during a manufacturing process of the semiconductor device or after a formation thereof.

Moreover, since a heat treating process or a cooling process is performed in the manufacturing process of the semiconductor device, the same level of CTE (Coefficient of Thermal Expansion) as that of a metal used as the wiring material is required. The reason for this is that if there is a big difference in the CTE between the interlayer dielectric and the wiring material, there occurs a difference in the degree of expansion or contraction of the interlayer dielectric and the wiring material during the heat treating process or the cooling process, resulting in a film peeling-off, a disconnection of wiring, or the like. Further, a thermal stability is also required. Especially, if the thermal stability of the fluorine-containing carbon film is low, the amount of degas of fluorine from the film increases, resulting in a problem such as a corrosion of wiring, a generation of a crack in the interlayer dielectric, or the like.

Though various kinds of gases are known as the source gas of the fluorine-containing carbon film, a C₅F₈ gas, for example, especially has a merit in that a decomposed product thereof is likely to create a stereostructure, and a C—F bond is resultantly enhanced, thus enabling an acquisition of an interlayer dielectric having a low dielectric constant, a small leakage current, and a high film strength or a high stress-resistant property. Patent Document 1 discloses a technology for obtaining a fluorine-containing carbon film having an original composition or structure of a source material while suppressing an excessive decomposition of the source material by lowering an electron temperature of plasma in a plasma film forming apparatus for converting the C₅F₈ gas into the plasma.

However, to realize the practical use of the fluorine-containing carbon film using the C₅F₈ gas as the source gas, its current leakage needs to be further reduced, and a mechanical strength such as a hardness or an elastic rate needs to be enhanced. Further, desirably, its CTE needs to be reduced closer to the CTE of the wiring material.

Here, disclosed in Patent Document 2 is a technology in which a C₄F₈ gas is used as a source gas of a fluorine-containing carbon film, wherein by adding a hydrogen gas to the C₄F₈ gas, a deposition speed of the fluorine-containing carbon film is ensured, a reduction of film thickness due to a heat treatment is lowered, and the obtained fluorine-containing carbon film is given a high adhesivity. However, this document does not mention anything about obtaining a sufficient mechanical strength or a high CTE compatibility with the wiring material by means of adding the hydrogen gas to the C₄F₈ gas. Thus, the problems intended to be solved by the present invention is deemed to be difficult to resolve by the technology of Patent Document 2.

Patent Document 1: Japanese Patent Application No. 2003-083292

Patent Document 2: Japanese Patent Laid-open Publication No. 2004-311625 (Paragraphs [0074], [0077] and [0078])

### DISCLOSURE OF THE INVENTION

In view of the foregoing, the present invention provides a technology capable of obtaining a fluorine-containing carbon film having desirable leakage property, coefficient of thermal expansion and mechanical strength.

For this reason, a film forming method in accordance with the present invention is for forming a fluorine-containing carbon film by using active species obtained by activating a C₅F₈ gas and a hydrogen gas. It is desirable that the hydrogen gas is mixed with the C₅F₈ gas such that a flow rate ratio of the hydrogen gas to the C₅F₈ gas is about 20% to 60%. Here, a gas selected from an octafluorocyclopentene gas, an octafluoropentyne gas and an octafluoropentadiene gas is used as the C₅F₈ gas. Further, the fluorine-containing carbon film is used as, for example, an insulating film included in a semiconductor device.

Further, a film forming method in accordance with the present invention includes: mounting a substrate to be subjected to a film forming process on a mounting unit in a processing vessel; introducing a plasma generating gas from an upper portion of the processing vessel; vacuum-exhausting an inside of the processing vessel from a lower side below the substrate; introducing a C₅F₈ gas into the processing vessel from between a position corresponding to a height at which the plasma generating gas is introduced and a position corresponding to a height of the substrate; introducing a hydrogen gas into the processing vessel; and converting the C₅F₈ gas and the hydrogen gas into a plasma by supplying a microwave into the processing vessel from a planar antenna member installed at the upper portion of the processing vessel to face the mounting table and provided with a number of slits along a circumferential direction.

Furthermore, a film forming apparatus in accordance with the present invention includes: an airtightly sealed processing vessel including therein a mounting unit for mounting a substrate thereon; a unit for supplying a C₅F₈ gas into the processing vessel; a unit for supplying a hydrogen gas into the processing vessel; a plasma generating unit for supplying an energy to the C₅F₈ gas and the hydrogen gas to convert the gases into a plasma; a unit for vacuum-evacuating an inside of the processing vessel; and a control unit for outputting a control instruction to each unit to introduce the C₅F₈ gas and the hydrogen gas into the processing vessel and to convert the gases into the plasma.

Here, it is desirable that the plasma generating unit includes: a waveguide for guiding a microwave into the processing vessel; and a planar antenna member connected to the waveguide, installed to face the mounting unit and provided with a number of slits along a circumferential direction, wherein the unit for supplying the C₅F₈ gas into the processing vessel introduces the C₅F₈ gas into the processing vessel from between a position corresponding to a height of a unit for supplying a plasma generating gas, which is to be excited by the microwave, into the processing vessel and a position corresponding to a height of the substrate mounted on the mounting unit.

Further, it is desirable that the film forming apparatus further includes: a flow rate control unit for controlling a flow rate of the C₅F₈ gas and a flow rate of the hydrogen gas supplied into the processing vessel, wherein the flow rate control unit is controlled by the control unit to mix the hydrogen gas with the C₅F₈ gas such that a flow rate ratio of the hydrogen gas to the C₅F₈ gas becomes about 20% to 60%. A gas selected from an octafluorocyclopentene gas, an octafluoropentyne gas and an octafluoropentadiene gas is used as the C₅F₈ gas.

Furthermore, a storage medium in accordance with the present invention is for storing therein a computer program executed on a computer and used in a film forming apparatus, wherein the computer program is composed of steps for executing the film forming method as described above. Further, a semiconductor device in accordance with the present invention includes an insulating film made of a fluorine-containing carbon film formed by one method among the above-described methods.

In accordance with the present invention, since the fluorine-containing carbon film is formed by using an active species obtained by activating the C₅F₈ gas and the hydrogen gas, the fluorine-containing carbon film having a small leakage current and a high mechanical strength such as a high hardness or a high elasticity can be obtained, as can be seen from the later described experimental examples.

### BRIEF DESCRIPTION OF THE DRAWINGS

FIG. 1 is an explanatory diagram for describing a formation of a fluorine-containing carbon film in accordance with an embodiment of the present invention;

FIGS. 2A to 2C are explanatory diagrams for describing a C₅F₈ gas used in the embodiment of the present invention;

FIG. 3 is a cross sectional view of a semiconductor device in accordance with the embodiment of the present invention;

FIG. 4 presents an explanatory diagram for describing a dissociation of the C₅F₈ gas used in the embodiment of the present invention;

FIG. 5 is a longitudinal side view illustrating an example plasma film forming apparatus for use in the embodiment of the present invention;

FIG. 6 depicts a plan view of a second gas supplying unit used in the plasma film forming apparatus;

FIG. 7 is a perspective view illustrating a partial cross section of an antenna unit used in the plasma film forming apparatus;

FIGS. 8A to 8C are characteristic diagrams showing an XPS analysis result of a fluorine-containing carbon film;

FIG. 9 is a characteristic diagram showing a hydrogen gas flow rate dependency of a leakage current of a fluorine-containing carbon film;

FIG. 10 is a characteristic diagram showing an electric field dependency of a leakage current of a fluorine-containing carbon film;

FIG. 11 provides a characteristic diagram showing an electric field dependency of a leakage current of a fluorine-containing carbon film;

FIG. 12 is a characteristic diagram showing a hydrogen gas flow rate dependency of a hardness of a fluorine-containing carbon film;

FIG. 13 is a characteristic diagram showing a hydrogen gas flow rate dependency of an elasticity of a fluorine-containing carbon film;

FIG. 14 sets forth a characteristic diagram showing a hydrogen gas flow rate dependency of a film forming speed of a fluorine-containing carbon film;

FIGS. 15A and 15B present characteristic diagrams showing a TDS analysis result of a fluorine-containing carbon film;

FIG. 16 is a characteristic diagram showing a variation of a film thickness of a fluorine-containing carbon film before and after a heat treatment;

FIG. 17 is a characteristic diagram showing a hydrogen gas flow rate dependency of a dielectric constant of a fluorine-containing carbon film;

FIG. 18 offers a characteristic diagram showing a plasma gas flow rate dependency of a dielectric constant of a fluorine-containing carbon film;

FIG. 19 is a characteristic diagram showing a leakage current and a dielectric constant of a fluorine-containing carbon film; and

FIGS. 20A to 20C are explanatory diagrams showing a bonding energy of each bond of a C₅F₈ gas and a C₄F₈ gas.

### BEST MODE FOR CARRYING OUT THE INVENTION

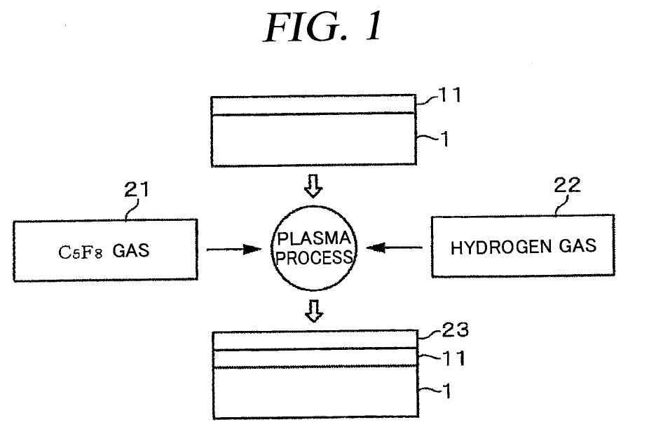

Hereinafter, an embodiment of a semiconductor device manufacturing method employing a film forming method in accordance with the present invention will be described. In the present embodiment, although a process of forming an insulating film made up of a fluorine-containing carbon film (CF film) is included, an embodiment of a method for forming an interlayer dielectric as the insulating film will be explained. FIG. 1 is a diagram for illustrating images of the manufacturing method in accordance with the present embodiment, and employed as a substrate 1 is one having a transistor circuit and a gate electrode formed on a surface thereof or one having thereon an n^{th} layer of a multilayer wiring structure.

Further, a C₅F₈ gas, which is a compound of carbon and fluorine, is used as a source gas 21 for forming the fluorine-containing carbon film on the substrate 1. In the present invention, a mixture gas 22 containing a hydrogen gas is used besides the source gas 21. Here, as for the mixture ratio of the hydrogen gas, it is desirable that a flow rate thereof relative to a flow rate of the C₅F₈ gas is about 20% to 80%, as can be seen from experimental examples to be described later.

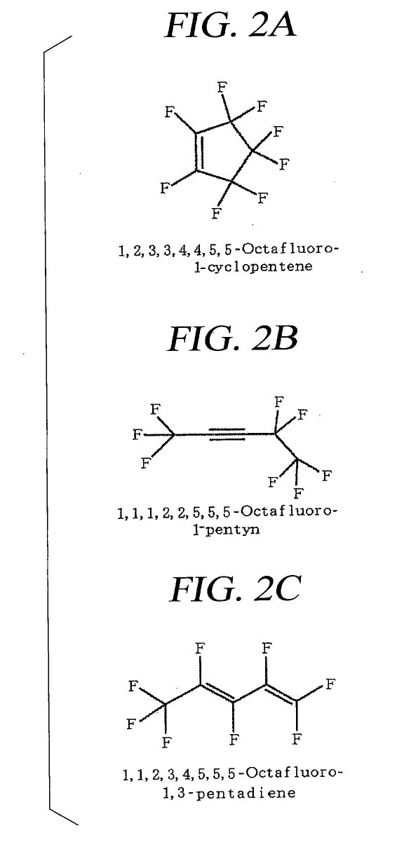

For example, as illustrated in FIGS. 2A to 2C, the C₅F₈ gas can be a cyclic C₅F₈ gas (1,2,3,3,4,4,5,5-Octafluoro-1-cyclopentene, see FIG. 2A), a straight-chain C₅F₈ gas having one triple bond (1,1,1,2,2,5,5,5-Octafluoro-1-pentyne, see FIG. 2B), a straight-chain C₅F₈ gas having conjugated double bonds (1,1,2,3,4,5,5,5-Octafluoro-1,3-pentadiene, see FIG. 2C), or the like.

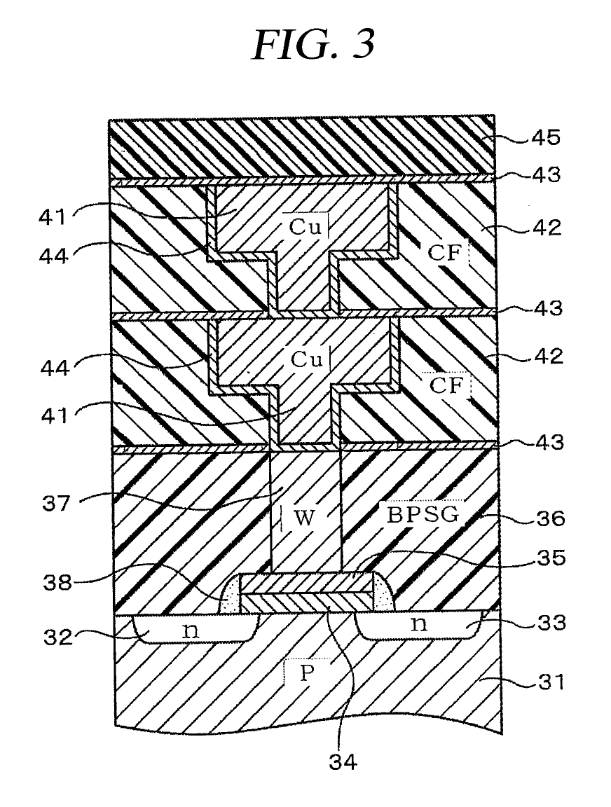

FIG. 3 shows an example semiconductor device including the interlayer dielectric formed by the present method. Reference numeral 31 represents a p-type silicon layer, reference numerals 32 and 33 represent n-type regions serving as a source and a drain, respectively, reference numeral 34 represents a gate oxide film and reference numeral 35 represents a gate electrode, and these components constitute a MOS transistor. Further, reference numerals 36 and 37 denote a BPSG film and a wiring made of, e.g., tungsten, respectively, and reference numeral 38 represents a side spacer. On the BPSG film 36, interlayer dielectrics 42 are laminated in multiple layers (FIG. 3 shows only two layers for the simplicity of explanation), wherein each interlayer dielectric is made up of a fluorine-containing carbon film of the present invention and has a wiring layer 41 made of, e.g., copper. Further, reference numeral 43 is a hard mask made of, e.g., silicon nitride; reference numeral 44 denotes a protective layer made of, e.g., titan nitride, tantalum nitride, or the like for preventing a diffusion of a wiring metal; and reference numeral 45 denotes a protective film.

The present invention is directed to form a fluorine-containing carbon film by converting the C₅F₈ gas and the hydrogen gas into plasma. If the C₅F₈ gas and the hydrogen gas are converted into the plasma, decomposed products containing carbon and fluorine of the C₅F₈ gas, which are contained in the plasma, are deposited on a surface of the substrate 1, so that the fluorine-containing carbon film 23 is formed, and active species of hydrogen act on the decomposed products or the fluorine-containing carbon film 23.

As can be seen from the experimental examples to be described later, though the dielectric constant of the fluorine-containing carbon film 23 formed by the above-described method increases slightly higher than that in case without adding the hydrogen gas to the C₅F₈ gas, it is still possible to obtain a dielectric constant of about 2.3 to 2.5 by adjusting the mixing amount of the hydrogen gas and to reduce a leakage current.

Moreover, it is also possible to obtain an elasticity of about 6 to 8 GPa and a hardness of about 0.6 to 0.8 GPa and an elasticity or hardness 1.5 times as great as that of a plastic material along with a good mechanical property. Therefore, a breakdown of the interlayer dielectric can be suppressed in the manufacturing process of the semiconductor device, e.g., in a CMP process even in case that a great force is applied thereto, and an impact that might be applied after the formation of the semiconductor device can be endured.

Moreover, since a coefficient of thermal expansion close to that of copper can be obtained, it is possible to suppress a film peeling-off or a disconnection between the wiring layer and the interlayer dielectric by using the copper which is useful as a wiring material and by using the fluorine-containing carbon film 23 as the interlayer dielectric between each wiring layer.

Furthermore, when a heat treatment is performed, a corrosion of wiring or a crack of the interlayer dielectric hardly occurs because a degassing of the fluorine or carbon is difficult to be generated. Furthermore, since a degassing amount is very small, a film thickness hardly changes before and after the heat treatment, and a thermal stability is good. Furthermore, since a film forming speed increases as a result of adding the hydrogen gas, it is also possible to obtain an effect of improving the efficiency of film formation by using a smaller amount of source gases.

As mentioned above, though the fluorine-containing carbon film 23 formed by converting the C₅F₈ gas and the hydrogen gas into the plasma has the slightly increased dielectric constant, the leakage current decreases while allowing for the enhancement of the mechanical strength such as the elasticity or the hardness, and its CTE compatibility with the copper, which is useful as the wiring layer, improves. Furthermore, since a basic film property such as the thermal stability or the film forming speed also improves, the fluorine-containing carbon film 23 of the present invention has a good characteristic as the insulating film. Especially, it is effective to form the wiring layers with the copper and to use the fluorine-containing carbon film of the present invention as the interlayer dielectric for insulating the wiring layers.

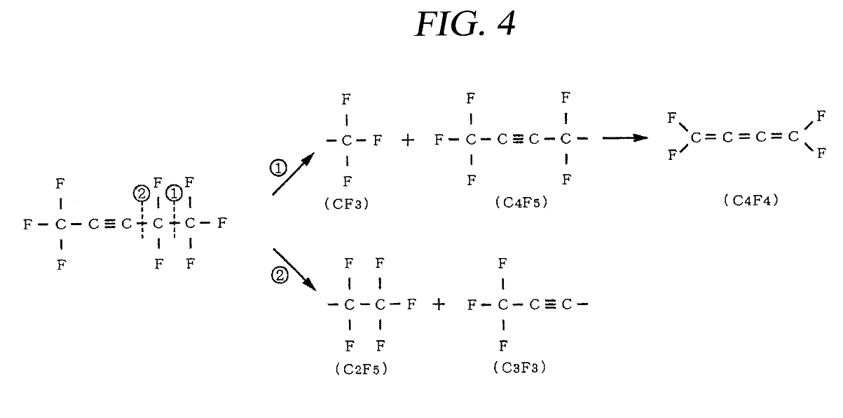

The inventors of the present invention have investigated the reason why the fluorine-containing carbon film 23 formed by converting the C₅F₈ gas and the hydrogen gas into the plasma has superior characteristics as the insulating film and figured it out as follows. As will be explained later, since the bonding energy of each bond in the C₅F₈ gas is great, an excessive dissociation is suppressed even when it is converted into the plasma. Further, as illustrated in FIG. 4 which exemplifies the straight-chain C₅F₈ gas having the triple bond, it is conjectured that the C₅F₈ gas is dissociated into C₄F₄ after it becomes —CF₃ and —C₄F₅ as a result of a cleavage of a C—C bond \textcircled{1} or dissociated into —C₂F₅ and —C₃F₃ as a result of a cleavage of a C—C bond \textcircled{2}. As described, since the decomposed products have a great number of C and a large molecular weight, the amount of C is more abundant when comparing the amount of C and F in the fluorine-containing carbon film. Generally, as is well known, it is easy to carry out a polymerization if an F/C ratio is no greater than 2.

Meanwhile, if the fluorine-containing carbon film is formed by mixing the hydrogen gas with the C₅F₈ gas and converting them into the plasma, F in the film escapes as it becomes HF, so that the polymerization becomes easier because the F/C ratio of the fluorine-containing carbon film is further lowered. However, as can be seen from the experimental examples to be described later, several tens of atomic % of H remains in the fluorine-containing carbon film 23. As a result, though the C, F and H exist together in the film, the thermal stability of the film is good, so that it is conjectured that the H becomes hydrocarbon and is kept in a stable state.

As described above, if the C₅F₈ gas and the hydrogen gas are used by being mixed with each other, vulnerable F in the fluorine-containing carbon film escapes, accelerating the polymerization and thus increasing multiple bonds. Further, since the H exists in the stable state, it is conjectured that a C-dangling bond present in the film is bonded with a C- or H-dangling bond and is terminated so that the C-dangling bond present in the film decreases.

This hypothesis also complies with the following facts: the dielectric constant slightly increases because of the increase of C—C bonds in the film; the leakage current is reduced as a result of the reduction of the C-dangling bond in the film due to the suppression of a generation of a leakage current caused by the presence of the dangling bond; the mechanical strength of the film is enhanced due to the increase of multiple bonds between the C atoms causing the film to be stronger; and the thermal stability improves due to the reduction of the escape of the F atoms during the heat treatment process because the amount of F in the film decreases.

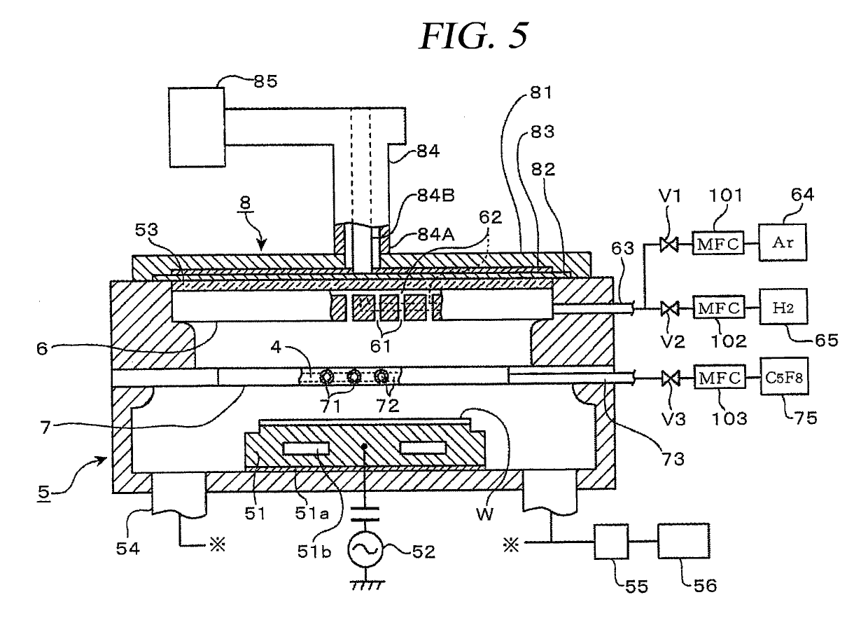

Now, a plasma film forming apparatus for forming the fluorine-containing carbon film 23 by converting the C₅F₈ gas and the hydrogen gas into the plasma will be simply explained with reference to FIGS. 5 to 7. This plasma film forming apparatus is a CVD (Chemical Vapor Deposition) apparatus for generating the plasma by using a radial line slot antenna. In the figures, reference numeral 5 denotes a processing vessel (vacuum chamber) having, for example, a cylindrical shape as a whole, and a sidewall and a bottom portion of the processing vessel 5 are made up of a conductor, e.g., aluminum containing stainless steel or the like, and a protective film made of aluminum oxide is formed on an inner wall surface.

A mounting table 51 serving as a mounting unit for mounting thereon a substrate, e.g., a wafer W, is installed in approximately a center of the processing vessel 5 by interposing an insulator 51a. The mounting table 51 is formed of, for example, aluminum nitride (AlN) or aluminum oxide (Al₂O₃), and incorporates therein a cooling jacket 51b through which a coolant is circulated; and a non-illustrated heater which constitutes a temperature control unit is installed along with the cooling jacket 51b. A mounting surface of the mounting table 51 is formed as an electrostatic chuck. Further, in the mounting table 51, a high frequency bias power supply 52 of, e.g., about 13.56 MHz is connected with a non-illustrated electrode, and by allowing the surface of the mounting table 51 to have a negative potential by using a bias high frequency wave, ions in the plasma can be injected with a high verticality.

A ceiling portion of the processing vessel 5 is opened, and a first gas supply unit 6 of, for example, a substantially circular plane shape is disposed in this ceiling portion via a seal member (not shown) such as an O ring so as to face the mounting table 51. The gas supply unit 6 is formed of, for example, aluminum oxide, and formed in its surface facing the mounting table 51 is a gas flow path 62 communicating with ends of gas supply holes 61. The gas flow path 62 is connected with one end of a first gas supply line 63. Meanwhile, the other end of the first gas supply line 63 is connected with a supply source 64 of a plasma generating gas (plasma gas) such as an argon (Ar) gas or a krypton (Kr) gas and a supply source 65 of a hydrogen gas serving as a mixture gas. These gases are supplied into the gas flow path 62 through the first gas supply line 63 and are uniformly supplied into a space below the first gas supply unit 6 through the gas supply holes 61.

In this example, the supply source 64, the first gas supply line 63 and the first gas supply unit 6 constitute a means for supplying the plasma generating gas into the processing vessel 5, while the supply source 65, the first gas supply line 63 and the first gas supply unit 6 constitute a means for supplying the hydrogen gas into the processing vessel 5.

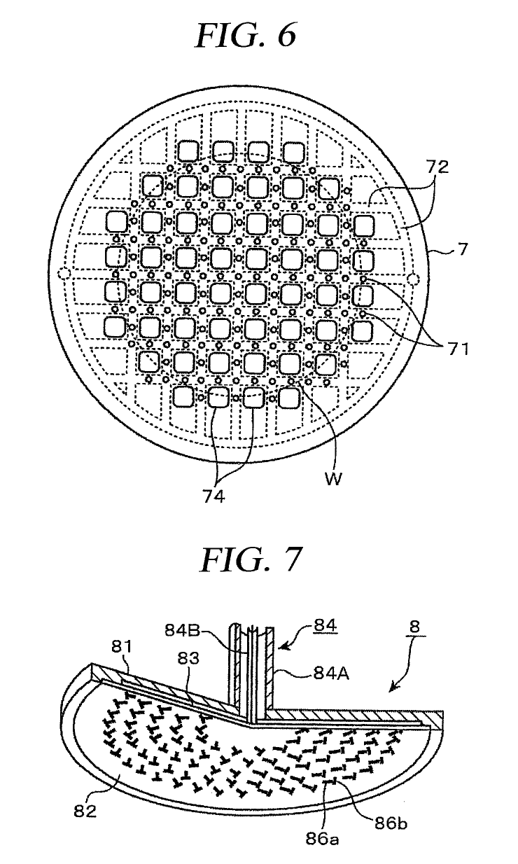

Further, the processing vessel 5 includes a second gas supply unit 7 of, for example, a substantially circular plane shape, provided between the mounting table 51 and the first gas supply unit 6 to divide them, for example. The second gas supply unit 7 is made up of a conductor such as an aluminum alloy containing, e.g., magnesium, or an aluminum containing stainless steel, and a number of gas supply holes 71 are provided in a surface facing the mounting table 51. Provided inside the gas supply unit 7 are, as shown in FIG. 6, grid-patterned gas flow paths 72 communicating with ends of the gas supply holes 71, and the gas flow paths 72 are connected to one end of a second gas supply line 73. Further, the second gas supply unit 7 is provided with a plurality of openings 74 which pass through the second gas supply unit 7. The openings 74 allow the plasma or a source gas in the plasma to pass therethrough to reach the space below the gas supply unit 7, and are provided between the adjacent gas flow paths 72, for example.

Here, the second gas supply unit 7 is connected with a supply source 75 of a C₅F₈ gas, which is the source gas, via the second gas supply line 73, and the C₅F₈ gas is sequentially flown into the gas flow paths 72 through the second gas supply line 73 and uniformly supplied into the space below the second gas supply unit 7 through the gas supply holes 71. In this example, the supply source 75, the second gas supply line 73 and the second gas supply unit 7 constitute a means for supplying the C₅F₈ gas into the processing vessel 5. In the figures, V1 to V3 are valves; reference numerals 101 to 103 are flow rate control means for controlling supply amounts of the Ar gas, the hydrogen gas and the C₅F₈ gas into the processing vessel 5, respectively.

A cover plate 53 formed of a dielectric material such as aluminum oxide is disposed above the first gas supply unit 6 via a seal member (not shown) such as an O ring, and an antenna unit 8 is provided on a top of the cover plate 53 to be in a close contact therewith. As shown in FIG. 7, the antenna unit 8 includes a flat antenna body 81 of a circular plane shape having an opening in a bottom surface thereof; and a circular plate shaped planar antenna member (slot plate) 82 disposed to block the opening in the bottom surface of the antenna body 81 and provided with a number of slots. The antenna body 81 and the planar antenna member 82 are both made of a conductor, and they form a flat hollow circular waveguide. Further, a bottom surface of the planar antenna member 82 is coupled to the cover plate 53.

In addition, between the planar antenna member 82 and the antenna body 81, there is disposed a wave shortening member 83 made of a low-loss dielectric material such as aluminum oxide or silicon nitride (Si₃N₄). The wave shortening member 83 serves to shorten a wavelength of a microwave to thereby shorten a wavelength in the circular waveguide. In the present embodiment, the antenna body 81, the planar antenna member 82 and the wave shortening member 83 together form a radial line slot antenna (RLSA).

The antenna unit 8 configured as described above is mounted on the processing vessel 5 via a seal member (not shown) such that the planar antenna member 82 makes a close contact with the cover plate 53. The antenna unit 8 is connected to an external microwave generating unit 85 via a coaxial waveguide 84, and supplies a microwave having a frequency of, for example, about 2.45 GHz or about 8.3 GHz. An outer waveguide 84A of the coaxial waveguide 84 is connected to the antenna body 81, and a central conductor 84B thereof is connected to the planar antenna member 82 through an opening provided in the wave shortening member 83.

The planar antenna member 82 is made of, e.g., a copper plate having a thickness of about 1 mm, and is provided with a plurality of slots 86 for generating, e.g., a circular polarized wave, as shown in FIG. 7. As for the formation of the slots 86, a pair of slots 86a and 86b, which are arranged in an approximate T-shape with a slight interval maintained therebetween, form a group, and the groups are concentrically or spirally arranged along a circumferential direction. Since the slots 86a and 86b are arranged substantially perpendicular to each other, the circular polarized wave including two perpendicular polarization wave components is radiated. By arranging each pair of slots 86a and 86b at an interval corresponding to a wavelength of the microwave compressed by the wave shortening member 83, the microwave is radiated as a substantially plane wave from the planar antenna member 82. In the present invention, the microwave generating unit 85, the coaxial waveguide 84 and the antenna unit 8 together constitute a plasma generating means.

Further, a gas exhaust pipe 54 is connected to a bottom portion of the processing vessel 5, and the gas exhaust pipe 54 is connected with a vacuum pump 56 serving as a vacuum exhaust means via a pressure control unit 55 serving as a pressure control means so that the inside of the processing vessel 5 can be vacuum-exhausted to a preset pressure level.

Here, in the above-described plasma film forming apparatus, the power supply to the microwave generating unit or the high frequency power supply 52, the opening/closing of the valves V1 to V3 for supplying the plasma gas or the source gas, the flow rate control units 101 to 103, the pressure control unit 55, and so forth are controlled by a non-illustrated control unit based on a program composed of steps for executing the film formation of the fluorine-containing carbon film under certain conditions. Further, at this time, it is also possible to store, in a storage medium such as a flexible disk, a compact disk, a flash memory or an MO (Magneto-Optical Disk), a computer program including steps for executing a control of each component such as the microwave generating unit 85 and the like, and to control each component based on this computer program so that the process is performed under preset conditions.

Hereinafter, an example of the film forming method in accordance with the present invention, which is performed by using the aforementioned apparatus, will be described. First, as a substrate, a wafer W, on the surface of which a copper wiring is formed, is loaded into the processing vessel 5 via a non-illustrated gate valve to be mounted on the mounting table 51. Subsequently, the inside of the processing vessel 5 is vacuum-exhausted to a preset pressure level. Further, a plasma gas, e.g., an Ar gas, to be excited by the microwave is supplied through the first gas supply line 63 into the first gas supply unit 6 at a preset flow rate of, for example, about 150 sccm, and a hydrogen gas as a mixture gas is supplied at a flow rate of about 50 sccm. Meanwhile, a C₅F₈ gas as a source gas is supplied through the second gas supply line 73 into the second gas supply unit 7 serving as the source gas supply unit at a predetermined flow rate of, for example, about 100 sccm. Then, the inside of the processing vessel 5 is maintained at a process pressure of, for example, about 7.32 Pa (55 mTorr), and a surface temperature of the mounting table 51 is set to be, for instance, about 420° C.

In the meantime, if a high frequency wave (microwave) of about 2.45 GHz and 2750 W is supplied from the microwave generating unit, the microwave propagates through the coaxial waveguide 84 in a TM mode, a TE mode or a TEM mode to reach the planar antenna member 82 of the antenna unit 8. Then, the microwave propagates radially from a central portion of the planar antenna member 82 toward a peripheral portion thereof via the inner conductor 84B of the coaxial waveguide, during which the microwave is radiated from the pair of slots 86a and 86b toward the processing space below the gas supply unit 6 via the cover plate 53 and the first gas supply unit 6.

Here, since the cover plate 53 and the first gas supply unit 6 are made of a material, such as aluminum, capable of transmitting the microwave therethrough, they function as a microwave transmitting window, so that the microwave is efficiently transmitted therethrough. At this time, since the pair of slits 86a and 86b are arranged as described above, a circular polarized wave is uniformly radiated over the entire plane of the planar antenna member 82, so that an electric field density in the processing space thereunder becomes uniform. By the energy of the microwave, plasma having high density and uniformity is excited over the entire region of the wide processing space. The plasma is flown into the processing space below the gas supply unit 7 through the openings 74 of the second gas supply unit 7, and activates the C₅F₈ gas supplied into the processing space from the gas supply unit 7, that is, converts the C₅F₈ gas into the plasma, thereby generating active species.

Here, if energy is given to the C₅F₈ gas and the hydrogen gas, the C₅F₈ gas is decomposed as described above and resultantly becomes film forming species. The film forming species transferred onto the wafer W in the aforementioned way are deposited thereon as a fluorine-containing carbon film. Though the active species of hydrogen act on the film forming species or the fluorine-containing carbon film, a CF film formed on each part of a pattern on the surface of the wafer W is removed by a sputter etching of Ar ions implanted into the wafer W by a plasma implantation bias voltage, and the fluorine-containing carbon film is formed from a bottom portion of a pattern groove while enlarging its region, so that the fluorine-containing carbon film is buried in recess portions. The wafer W on which the fluorine-containing carbon film is formed in this way is unloaded from the processing vessel 5 via the non-illustrated gate valve. In the foregoing, the series of operations of loading the wafer W into the processing vessel 5, performing the process under the preset conditions, and unloading it from the processing vessel 5 are executed by controlling each component by means of the control unit or the program stored in the storage medium.

If the fluorine-containing carbon film is formed by using the above-described apparatus, the C₅F₈ gas can be activated by microwave plasma having a low electron temperature not higher than about 3 eV. Therefore, an excessive dissociation of the C₅F₈ gas does not progress, and an excessive decomposition can be suppressed, so that an original molecular structure still having the characteristic of the C₅F₈ gas can be obtained. Accordingly, it is possible to form a fluorine-containing carbon film having a low dielectric constant, a low leakage current, a great mechanical strength and a good thermal stability.

Moreover, in the above described apparatus, it is also possible to supply the hydrogen gas into the processing vessel 5 through the second gas supply unit 7, as in the case of supplying the C₅F₈ gas. Further, the method of the present invention can also be performed by an apparatus other than the above-described plasma film forming apparatus as long as the other apparatus is capable of suppressing the excessive dissociation of the C₅F₈ gas and activating the C₅F₈ gas such that the original molecular structure maintaining the characteristic of the C₅F₈ gas can be obtained.

### Experimental Examples

A. Regarding the composition of the fluorine-containing carbon film

### Experimental Example 1

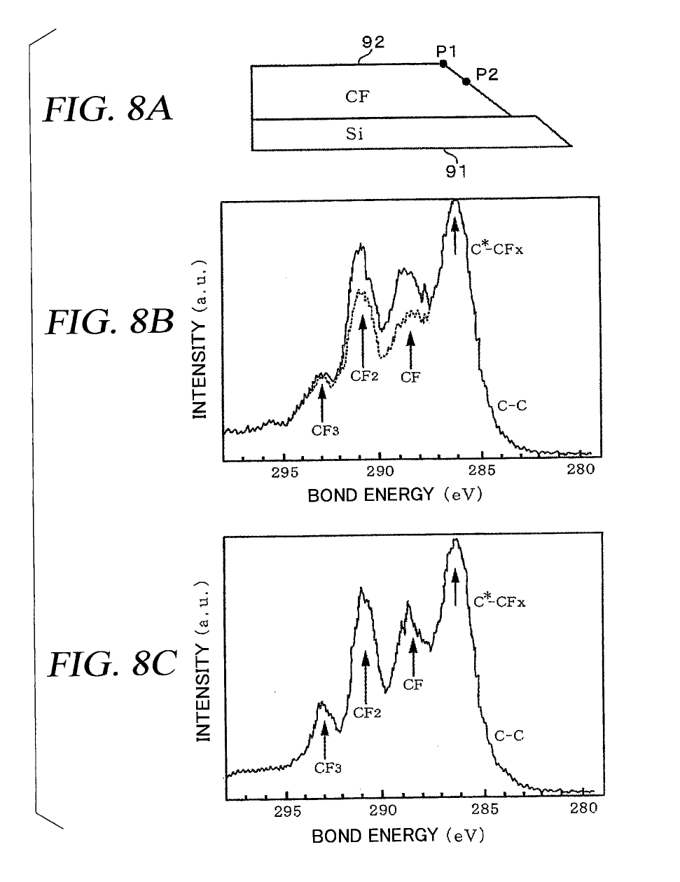

By using the plasma film forming apparatus of FIG. 5, a fluorine-containing carbon film 92 was formed on a silicon bare wafer 91, which is a substrate, in a thickness of about 150 nm, as shown in FIG. 8A, and a chemical bonding state of atoms constituting the fluorine-containing carbon film 92 was examined by performing an XPS (X-ray Photoelectron Spectroscopy) analysis on a surface position P1 of the fluorine-containing carbon film 92 and an inside position P2 of the fluorine-containing carbon film 92. The measurement at the position P2 was performed by cutting the fluorine-containing carbon film 92 through the positions P1 to P2, as shown in FIG. 8A. Here, film forming conditions for the fluorine-containing carbon film were the same as described above, and as a C₅F₈ gas, a straight chain C₅F₈ gas having a triple bond as shown in FIG. 2B was used. The result is shown in FIG. 8B wherein a solid line and a dashed line indicate the chemical bonding states of the atoms in the film at the surface position P1 and at the inside position P2, respectively.

### Comparative Example 1

A fluorine-containing carbon film 92 was formed under the same conditions as those of the Experimental example 1 except that the formation of the fluorine-containing carbon film was performed by using a C₅F₈ gas and an Ar gas at flow rates of about 200 sccm and about 150 sccm, respectively, without using a hydrogen gas as a mixture gas. Likewise, the XPS analysis was performed with respect to the surface position P1 and the inside position P2 of the fluorine-containing carbon film 92. The result is provided in FIG. 8C wherein though a solid line indicates a chemical bonding state of atoms in the film at the surface position P1, it is actually difficult to distinguish data of the surface position P1 and the inside position P2 from each other, and it can be seen that the chemical bonding states of the atoms in the film at the surface position P1 and the inside position P2 are substantially coincident.

Here, in FIGS. 8B and 8C, a horizontal axis represents a bond energy and a vertical axis represents an intensity. From these XPS analysis results, it was acknowledged that though there was substantially no variation in the composition of the fluorine-containing carbon film between the surface position P1 and the inside position P2 in the fluorine-containing carbon film 92 of Comparative example 1, there occurred a variation in the composition of the fluorine carbon containing film 92 between the surface position P1 and the inside position P2 in the fluorine-containing carbon film 92 of Experimental example 1.

Further, it was also acknowledged that there hardly occurred a variation in the composition of the fluorine-containing carbon film 92 in the surface position P1 depending on whether the hydrogen gas was added or not, whereas, in the inside position P2, peaks due to a CF₃ bond, a CF₂ bond and a CF bond are reduced while peaks due to a C—C bond and a C*—CFₓ bond are increased, as a result of adding the hydrogen gas, so that the amounts of presence of the CF₃ bond, the CF₂ bond and the CF bond are reduced, while the amounts of presence of the C—C bond and the C*—CFₓ bond are increased. Moreover, though the increment of the C—C bond was difficult to detect from FIGS. 8A to 8C, its increase from about 2.5% to about 5.5% was confirmed based on quantitative data for each component.

### Experimental Example 2

A HFS (Hydrogen Front Scattering) analysis was performed with respect to the fluorine-containing carbon film 92 of the Experimental example 1. The analysis result showed that the fluorine-containing carbon film 92 contains about 53.2 atomic % of carbon, about 34.5 atomic % of fluorine, and about 12.3 atomic % of hydrogen.

From the results of the XPS analysis and the HFS analysis, it was confirmed that as a result of mixing the hydrogen gas with the C₅F₈ gas, C, F and H exist in the fluorine-containing carbon film, and the amount of F decreases while the C—C bond increases in comparison with the case without adding the hydrogen gas. This result implies that H is mixed into the fluorine-containing carbon film during the film forming process and thus F in the film comes off together with H, so that the amount of F decreases, resulting in the increase of the C—C bond, a multiple bond, or a C—H bond.

### B. Regarding a Leakage Characteristic

### Experimental Example 3

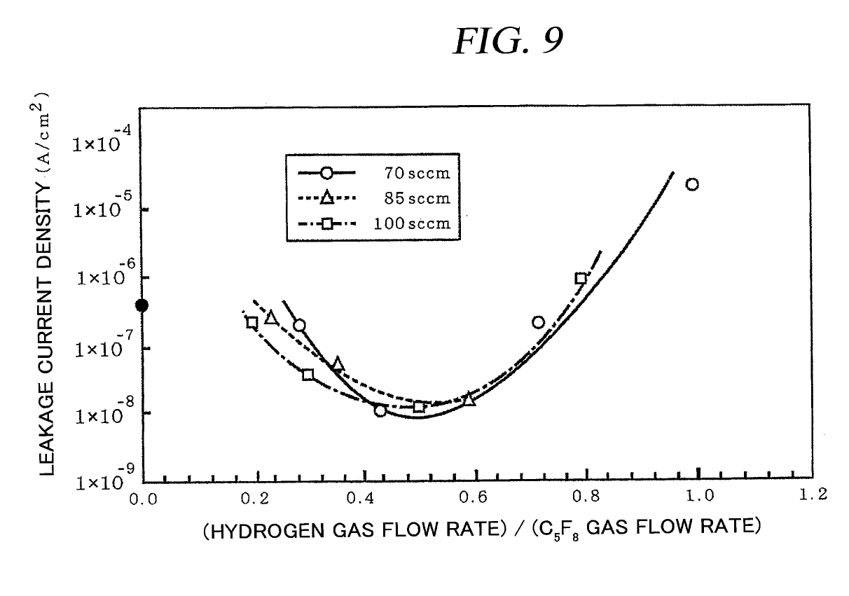

By using the plasma film forming apparatus of FIG. 5, fluorine-containing carbon films were formed while varying the amount of the C₅F₈ gas and the amount of the hydrogen gas individually, and a leakage current of each fluorine-containing carbon film was measured, so that a result as shown in FIG. 9 was obtained. In FIG. 9, a horizontal axis represents (hydrogen gas flow rate)/(C₅F₈ gas flow rate), and a vertical axis indicates a leakage current density when an electric field of about 1 MV/cm was applied. In the figure, ◯, Δ and □ represent data when the C₅F₈ gas flow rate was about 70 sccm, 85 sccm and 100 sccm, respectively. Further, in the drawing, indicates data in case that the hydrogen gas was not mixed (the C₅F₈ gas flow rate was about 200 sccm). In addition, as the C₅F₈ gas, the straight chain C₅F₈ gas having a triple bond as shown in FIG. 2B was employed, and conditions for the film formation were identical with those of Experimental example 1 except the flow rates of the C₅F₈ gas and the hydrogen gas.

As a result, as for the leakage current; it was found that when using the mixture of the C₅F₈ gas and the hydrogen gas, the leakage current varies depending on the mixing amount of the hydrogen gas, and the leakage current tends to increase rapidly if the mixing amount of the hydrogen gas exceeds a certain level, though the leakage current decreases in comparison with the case without mixing the hydrogen gas as long as the flow rate ratio ((hydrogen gas flow rate)/(C₅F₈ gas flow rate)) ranges from about 0.2 to 0.5. Here, when the flow rate ratio is about 0.8, the level of the leakage current is almost the same as that of the case without mixing the hydrogen gas, and when the flow rate ratio is about 1.0, the leakage current rapidly increases higher than that of the case without mixing the hydrogen case. Thus, to reduce the leakage current smaller than that of the case without mixing the hydrogen gas, it is deemed to be desirable to set the flow rate ratio to be in a range of about 0.2 to 0.8, i.e., the hydrogen gas flow rate is set to be no smaller than 20% of the C₅F₈ gas flow rate but no greater than 80% thereof.

### Experimental Example 4

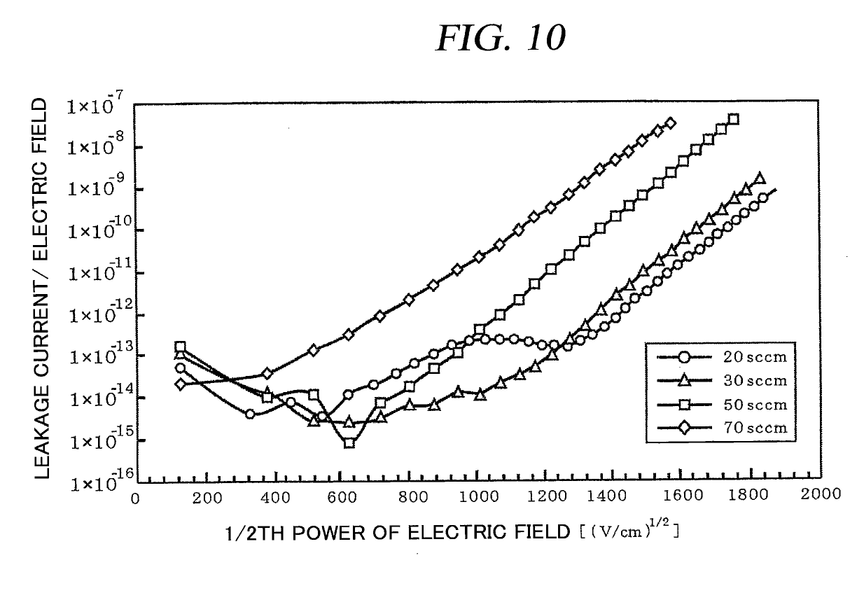

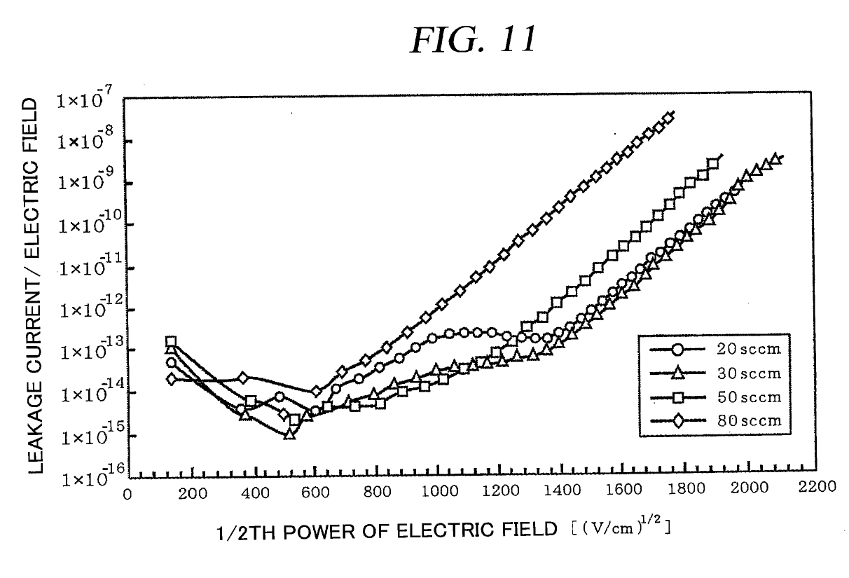

Further, measurement of an electric field dependence of a leakage current was performed by setting the C₅F₈ gas flow rate to be about 70 sccm and 100 sccm, and varying the mixing amount of the hydrogen gas. FIG. 10 shows the result when the C₅F₈ gas flow rate was 70 sccm, and FIG. 11 shows the result when the C₅F₈ gas flow rate was 100 sccm. In each figure, a horizontal axis represents a value corresponding to the ½th power of an electric field, while a vertical axis indicates a value corresponding to (leakage current)/(electric field), ◯, Δ, □ and ⋄ represent data when the hydrogen gas flow rate was about 20 sccm, 30 sccm, 50 sccm and 70 sccm, respectively. Further, as the C₅F₈ gas, the straight chain C₅F₈ gas having a triple bond as shown in FIG. 2B was employed, and the film formation was performed under the same conditions as those of Experimental example 1 except the flow rates of the C₅F₈ gas and the hydrogen gas.

As a result, it was acknowledged that the value of (leakage current)/(electric field) gradually decreases as the electric field increases until the value of the ½th power of the electric field reaches about 600 to 700 (V/cm)^{1/2} and about 500 to 600 (V/cm)^{1/2} when the C₅F₈ gas flow rate was 70 sccm and 100 sccm, respectively, whereas thereafter the value of (leakage current)/(electric field) gradually increases as the electric field increases, and the value of (leakage current)/(electric field) increases as the mixing amount of the hydrogen gas increases. From this result, it can also be seen that the leakage current varies depending on the mixing amount of the hydrogen gas and that the reduction of the leakage current can be accomplished by optimizing the amount of the hydrogen gas mixed with the C₅F₈ gas.

### C. Regarding Mechanical Strength

### Experimental Example 5

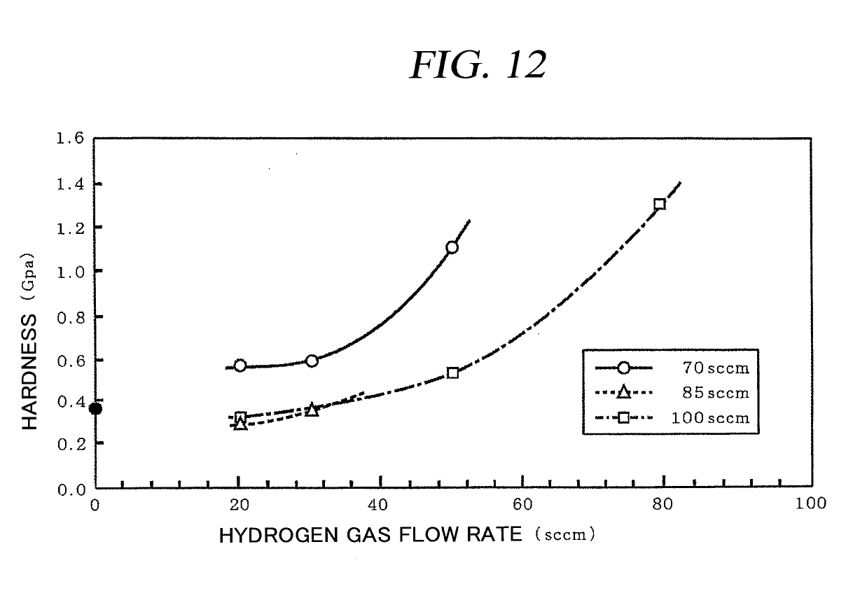

By using the plasma film forming apparatus of FIG. 5, fluorine-containing carbon films were formed while varying the amount of the C₅F₈ gas and the amount of the hydrogen gas individually, and a hardness of each fluorine-containing carbon film was measured, so that a result as shown in FIG. 12 was obtained. The measurement of the hardness was performed by a nano-indentation method. In FIG. 12, a horizontal axis represents a hydrogen gas flow rate, and a vertical axis indicates a hardness. In the figure, ◯, Δ and □ represent data when the C₅F₈ gas flow rate was about 70 sccm, 85 sccm and 100 sccm, respectively. Further, in the figure, indicates data in case without mixing the hydrogen gas (the C₅F₈ gas flow rate was about 200 sccm). In addition, as the C₅F₈ gas, the straight chain C₅F₈ gas having a triple bond as shown in FIG. 2B was employed, and conditions for the film formation were identical with those of Experimental example 1 except the flow rates of the C₅F₈ gas and the hydrogen gas.

As a result, it was acknowledged that when the hydrogen gas is added, the hardness of the obtained fluorine-containing carbon film rapidly increases as the mixing amount of the hydrogen gas increases, in comparison with the case without mixing the hydrogen gas in which the hardness was just about 0.35 GPa. Further, it was also confirmed that when the C₅F₈ gas flow rate was about 70 sccm, the hardness becomes equal to or greater than about 0.6 GPa if the hydrogen gas flow rate becomes about 30 sccm or greater (i.e., if the flow rate ratio of the hydrogen gas to the C₅F₈ gas becomes equal to or greater than about 43%); and when the C₅F₈ gas flow rate was 100 sccm, the hardness becomes equal to or greater than about 0.6 GPa if the hydrogen gas flow rate becomes about 55 sccm or greater (i.e., if the flow rate ratio of the hydrogen gas to the C₅F₈ gas becomes no smaller than about 55%).

### Experimental Example 6

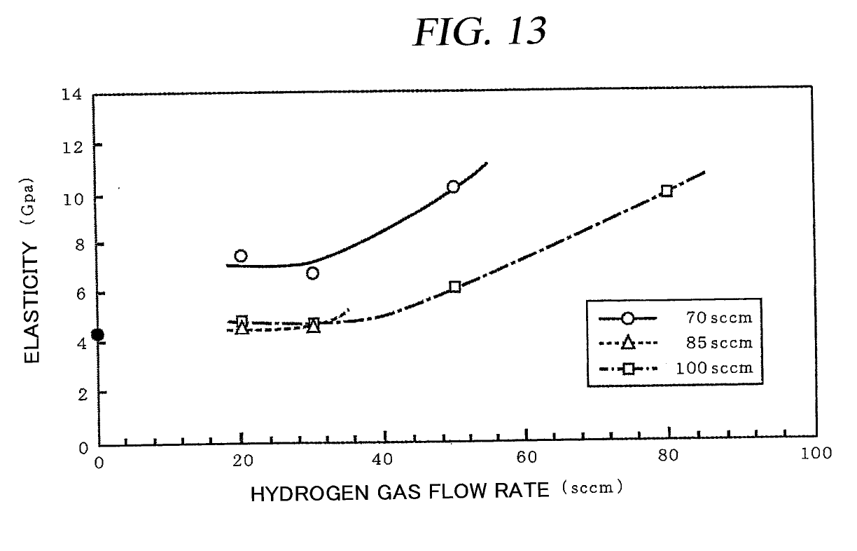

By using the plasma film forming apparatus of FIG. 5, fluorine-containing carbon films were formed while varying the amount of the C₅F₈ gas and the amount of the hydrogen gas individually, and elasticity of each fluorine-containing carbon film was measured, so that a result as shown in FIG. 13 was obtained. The measurement of the elasticity was performed by a nano-indentation method. In FIG. 13, a horizontal axis represents a hydrogen gas flow rate, and a vertical axis indicates an elasticity. In the figure, ◯, Δ and □ represent data when the C₅F₈ gas flow rate was about 70 sccm, 85 sccm and 100 sccm, respectively. Further, in the figure, indicates data in case without mixing the hydrogen gas (the C₅F₈ gas flow rate was about 200 sccm). In addition, as the C₅F₈ gas, the straight chain C₅F₈ gas having a triple bond as shown in FIG. 2B was employed, and conditions for the film formation were identical with those of Experimental example 1 except the flow rates of the C₅F₈ gas and the hydrogen gas.

As a result, it was acknowledged that when the hydrogen gas is added, the elasticity of the obtained fluorine-containing carbon film rapidly increases as the mixing amount of the hydrogen gas increases, in comparison with the case without mixing the hydrogen gas in which the elasticity was just about 4.4 GPa. Further, it was also confirmed that when the C₅F₈ gas flow rate was about 70 sccm, the elasticity becomes equal to or greater than about 6 GPa if the hydrogen gas flow rate becomes about 20 sccm or greater (i.e., if the flow rate ratio of the hydrogen gas to the C₅F₈ gas becomes equal to or greater than about 29%); and when the C₅F₈ gas flow rate was about 100 sccm, the elasticity becomes equal to or greater than about 6 GPa if the hydrogen gas flow rate becomes about 50 sccm or greater (i.e., if the flow rate ratio of the hydrogen gas to the C₅F₈ gas becomes no smaller than about 50%).

As can be confirmed from the above, the hardness and the elasticity of the fluorine-containing carbon film increase as the mixing amount of the hydrogen gas with the C₅F₈ gas increases, so that it is possible to obtain a fluorine-containing carbon film featuring a hardness of about 0.6 to 0.8 GPa or more and an elasticity of about 6 to 8 GPa or more.

### Experimental Example 7

In Experimental examples 5 and 6, a coefficient of thermal expansion was measured for each of the fluorine-containing carbon film obtained by using the C₅F₈ gas flow rate of about 70 sccm and the hydrogen gas flow rate of about 20 sccm, and the fluorine-containing carbon film obtained by using the C₅F₈ gas flow rate of about 100 sccm and the hydrogen gas flow rate of about 50 sccm. The measurement of the coefficient of thermal expansion was carried out by an XRR (X-Ray Reflectometry) method.

As a result, the coefficient of thermal expansion of the fluorine-containing carbon film, which was formed with the C₅F₈ gas flow rate of about 70 sccm and the hydrogen gas flow rate of about 20 sccm, was about 48 ppm, and the coefficient of thermal expansion of the fluorine-containing carbon film, which was formed with the C₅F₈ gas flow rate of about 100 sccm and the hydrogen gas flow rate of about 50 sccm, was about 39 ppm. Thus, it was confirmed that the coefficients of thermal expansion in both cases were smaller than a coefficient of thermal expansion in case without mixing the hydrogen gas (70 ppm), and approached a coefficient of thermal expansion of copper (20 ppm).

### D. Regarding Film Forming Speed

### Experimental Example 8

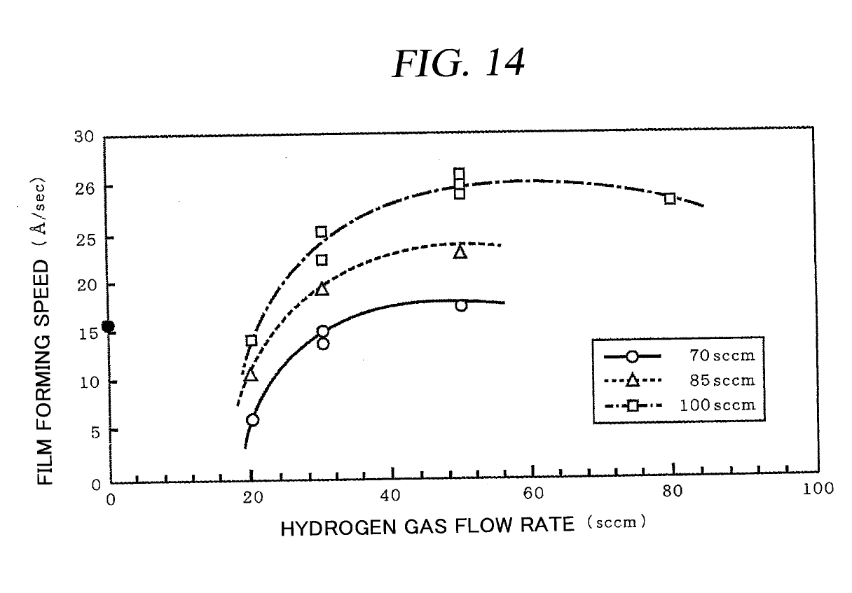

By using the plasma film forming apparatus of FIG. 5, fluorine-containing carbon films were formed while varying the amounts of the C₅F₈ gas and the hydrogen gas individually, and a film forming speed of each fluorine-containing carbon film was measured, so that a result as shown in FIG. 14 was obtained. In FIG. 14, a horizontal axis represents a hydrogen gas flow rate, and a vertical axis indicates a film forming speed. In the figure, ◯, Δ, □ indicate data when the C₅F₈ gas flow rate was about 70 sccm, 85 sccm and 100 sccm, respectively, and indicates data in case without mixing the hydrogen gas (the C₅F₈ gas flow rate was about 200 sccm). Further, as the C₅F₈ gas, the straight chain C₅F₈ gas having a triple bond as shown in FIG. 2B was used, and conditions for the film formation were identical with those of Experimental example 1 except the flow rates of the C₅F₈ gas and the hydrogen gas.

As a result, it was acknowledged that the film forming speed increases as the mixing amount of the hydrogen gas increases until the hydrogen gas flow rate reaches about 50 sccm, though the film forming speed is smaller than that in the case without mixing the hydrogen gas if the mixing amount of the hydrogen gas is small. Accordingly, the result implies that the film forming speed can be enhanced by optimizing the mixing amount of the hydrogen gas.

### E. Regarding Thermal Stability

### Experimental Example 9

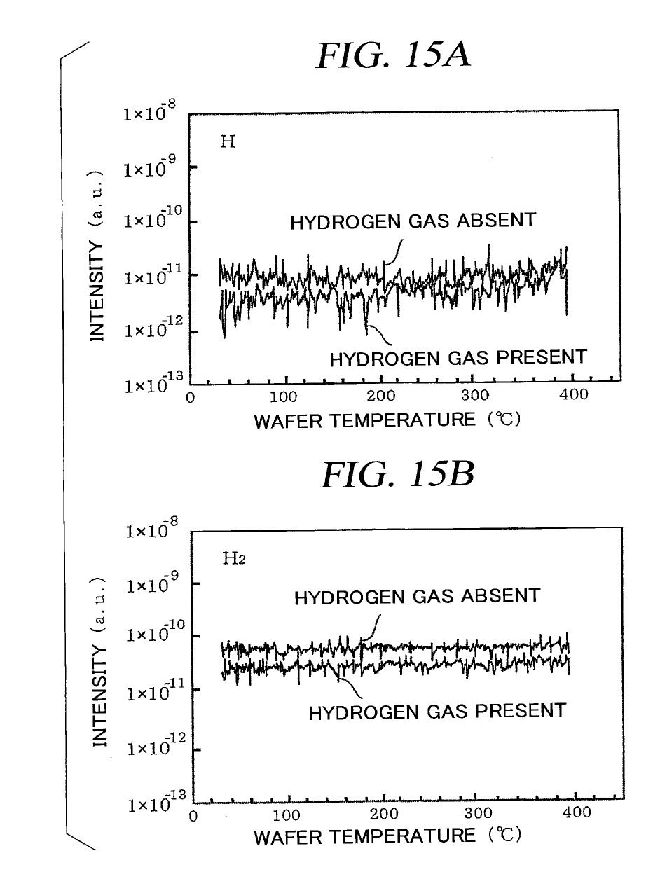

By using the plasma film forming apparatus of FIG. 5, a fluorine-containing carbon film was formed, and a TDS (Thermal Desorption Spectrometry) analysis was performed with respect to desorption components H and H₂ from the fluorine-containing carbon film. The formation of the fluorine-containing carbon film was performed under the same conditions as described above, and, as a C₅F₈ gas, the straight chain C₅F₈ gas having a triple bond as shown in FIG. 2B was used. FIG. 15A shows an analysis result of the desorption component H, and FIG. 15B shows an analysis result of the desorption component H₂. Further, the TDS analysis was also performed for the case without mixing the hydrogen gas (the C₅F₈ gas flow rate was 200 sccm), and the result is shown in FIGS. 15A and 15B together. In each of FIGS. 15A and 15B, a horizontal axis represents a wafer temperature, and a vertical axis indicates a detected intensity of desorption component.

As a result, it was confirmed that the detected intensities of the desorption components H and H₂ are almost constant regardless of the wafer temperature, and desorption of H and H₂ does not occur even when the fluorine-containing carbon film is heated up to 400° C. From this result, it was confirmed that the fluorine-containing carbon film formed by converting the C₅F₈ gas and the hydrogen gas into plasma has a high thermal stability, and H components in the fluorine-containing carbon film exist in a stable state.

### Experimental Example 10

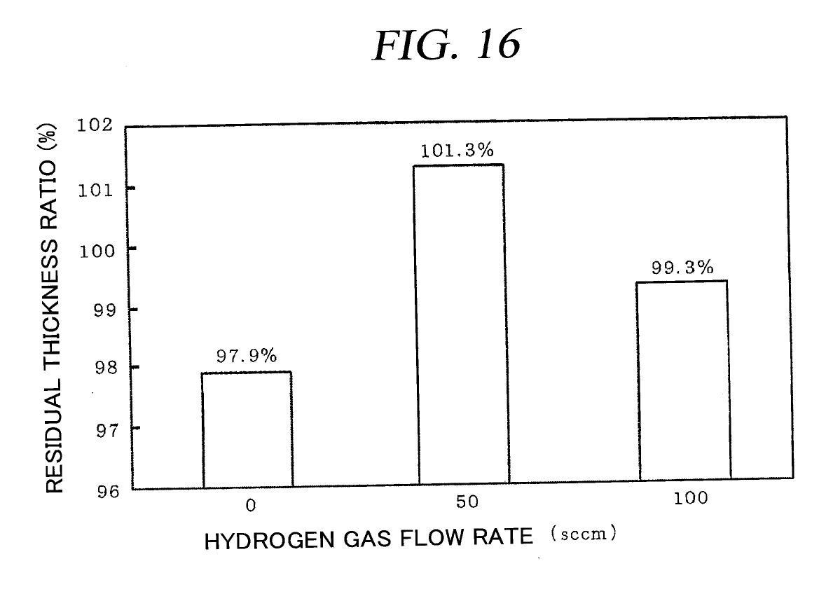

Further, by using the plasma film forming apparatus of FIG. 5, fluorine-containing carbon films were formed while varying the hydrogen gas flow rate, and a decrement of a film thickness of each fluorine-containing carbon film before and after a heat treatment was measured, and the result is shown in FIG. 16. The conditions for the film formation of the fluorine-containing carbon film were identical with those described above except that the C₅F₈ gas flow rate was set to be about 200 sccm, and, as the C₅F₈ gas, the straight chain C₅F₈ gas having a triple bond as shown in FIG. 2B was used. Further, the heat treatment was performed at a temperature of about 400° C. for about 60 minutes.

In FIG. 16, a horizontal axis represents a hydrogen gas flow rate, and a vertical axis indicates a residual thickness ratio. A residual thickness ratio of 100% implies that there is no difference in the film thickness before and after the heat treatment; a residual thickness ratio greater than 100% implies that the film thickness has increased by the heat treatment; and a residual thickness ratio smaller than 100% implies that the film thickness has decreased by the heat treatment. As a result, it was confirmed that when the hydrogen gas is mixed, the residual thickness ratio approaches 100%, and a variation in the film thickness before and after the heat treatment is much smaller than that in the case without mixing the hydrogen gas. This result implies that the amount of fluorine or hydrogen (the amount of degas) desorbed from the fluorine-containing carbon film during the heat treatment is very small, and thus the thermal stability of the fluorine-containing carbon film is high.

### F. Regarding Dielectric Constant

### Experimental Example 11

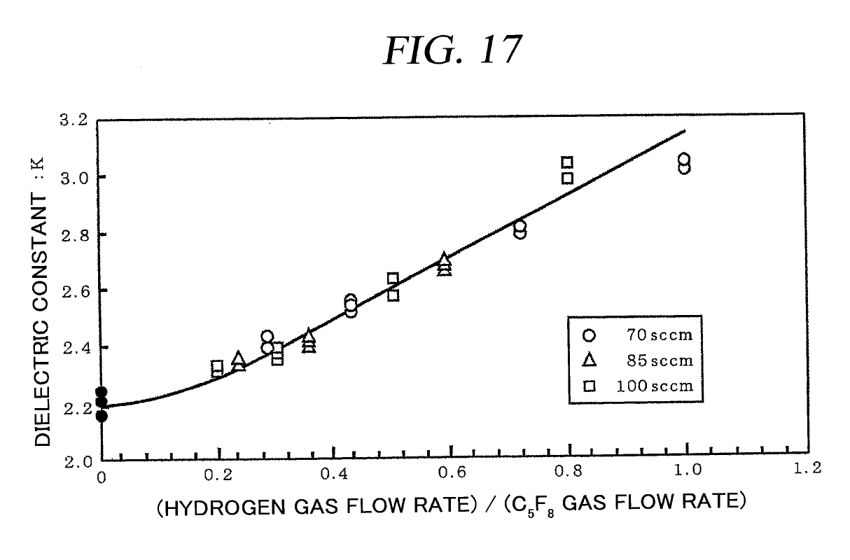

By using the plasma film forming apparatus of FIG. 5, fluorine-containing carbon films were formed while varying the amounts of the C₅F₈ gas and the hydrogen gas individually, and a dielectric constant of each fluorine-containing carbon film was measured, so that a result as shown in FIG. 17 was obtained. In FIG. 17, a horizontal axis represents (hydrogen gas flow rate)/(C₅F₈ gas flow rate), and a vertical axis indicates a dielectric constant. In the figure, ◯, Δ and □ indicate data when the C₅F₈ gas flow rate was about 70 sccm, 85 sccm and 100 sccm, respectively, and indicates data in case without mixing the hydrogen gas (the C₅F₈ gas flow rate was 200 sccm). Further, as the C₅F₈ gas, the straight chain C₅F₈ gas having a triple bond as shown in FIG. 2B was used, and conditions for the film formation were identical with those of Experimental example 1 except the flow rates of the C₅F₈ gas and the hydrogen gas.

As a result, when the hydrogen gas is not mixed, the dielectric constant was about 2.2, and it was confirmed that the dielectric constant increases in proportion to the mixing amount of the hydrogen gas. Further, from this data, it can be seen that a flow rate ratio ((hydrogen gas flow rate)/(C₅F₈ gas flow rate)) desirably needs to be in a range of about 0.2 to 0.6 to obtain a dielectric constant lower than that of a currently utilized low-k film, e.g., a SiCOH film; about 0.2 to 0.5 to be distinguished from the SiCOH film or the like; and about 0.2 to 0.4 to obtain a next-generation low-k film which requires a dielectric constant of about 2.3 to 2.5.

### Experimental Example 12

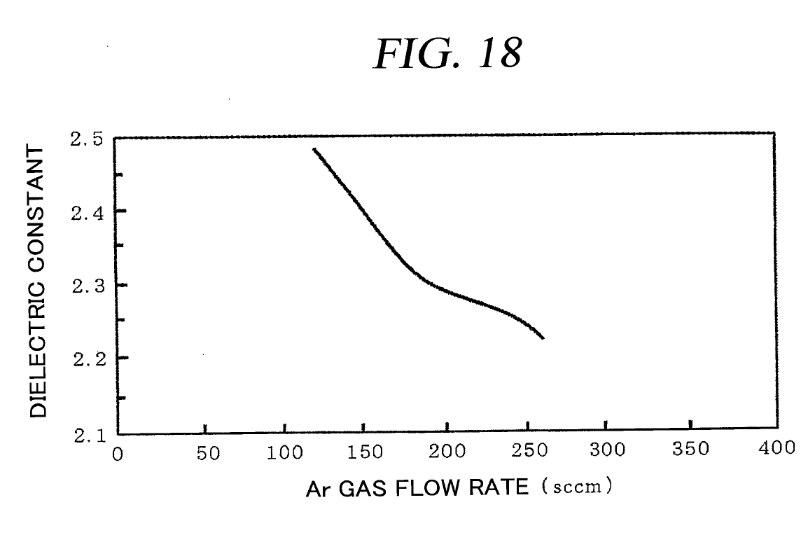

Further, a dependency of the dielectric constant upon a plasma gas flow rate was examined. By using the plasma film forming apparatus of FIG. 5, fluorine-containing carbon films were formed with a C₅F₈ gas flow rate of about 70 sccm and a hydrogen gas flow rate of about 20 sccm, while varying the flow rate of an Ar gas serving as a plasma gas between about 100 sccm and 250 sccm, and a dielectric constant of each fluorine-containing carbon film was measured, and the result is shown in FIG. 18. In the figure, a horizontal axis represents an Ar gas flow rate, and a vertical axis indicates a dielectric constant.

As a result, it was found that the dielectric constant of the fluorine-containing carbon film decreases with the increase of the Ar gas flow rate within the Ar gas flow rate ranging from about 100 sccm and 250 sccm. The reason for this is deemed to be as follows. In the plasma film forming apparatus of FIG. 5, though the C₅F₈ gas is supplied from the second gas supply unit 7 toward the mounting table 51, dissociated components of the C₅F₈ gas may be moved to an upper side above the second gas supply unit 7 while passing through it in the processing vessel 5.

Here, in the processing vessel 5, an electron temperature in the upper side above the second gas supply unit 7 is higher than that in the lower side therebelow. Thus, if the C₅F₈ gas is introduced into the region above the second gas supply unit 7, the C₅F₈ gas is divided into pieces because a dissociation thereof progresses excessively. Therefore, in case that the amount of the C₅F₈ gas moving toward the upper side through the second gas supply unit 7 is great, the C₅F₈ is divided by the excessive dissociation thereof, so that components having a small number of C and a small molecular weight increase. As a result, an original molecular structure of the C₅F₈ gas cannot be maintained, and the characteristic of the obtained fluorine-containing carbon film is deteriorated, resulting in an increase of a dielectric constant.

Meanwhile, if the Ar gas flow rate is increased, since a great amount of Ar gas is supplied to the upper side above the second gas supply unit 7, it becomes difficult for the C₅F₈ gas to move to the upper side above the second gas supply unit 7. Accordingly, it is believed that the amount of the C₅F₈ gas moving toward the upper side through the second gas supply unit 7 would decrease, and the excessive dissociation of the C₅F₈ gas would be suppressed, so that the original molecular structure of the C₅F₈ gas can be maintained, and the deterioration of the characteristic of the obtained fluorine-containing carbon film would be suppressed, thus enabling a reduction of the dielectric constant. Thus, it is expected to obtain a fluorine-containing carbon film having a dielectric constant of about 2.1 to 2.3 by attempting to optimize the mixing amount of the hydrogen gas and the amount of the plasma gas with respect to the C₅F₈ gas.

G. Comparison with the Case of Using a C₄F₈ Gas and a Hydrogen Gas

### Experimental Example 13

By using the plasma film forming apparatus of FIG. 5, fluorine-containing carbon films were formed while varying the flow rates of the C₅F₈ gas and the hydrogen gas, and a dielectric constant and a leakage current were measured. Further, as a comparative example, a dielectric constant and a leakage current were also measured for fluorine-containing carbon films formed by using only a C₅F₈ gas (without adding the hydrogen gas) and by using a C₄F₈ gas and a hydrogen gas, respectively. Further, since the measurement of the leakage current was performed here under the atmosphere of nitrogen, the measurement values are much smaller than the aforementioned leakage current values (e.g., FIG. 9) obtained under the atmospheric atmosphere.

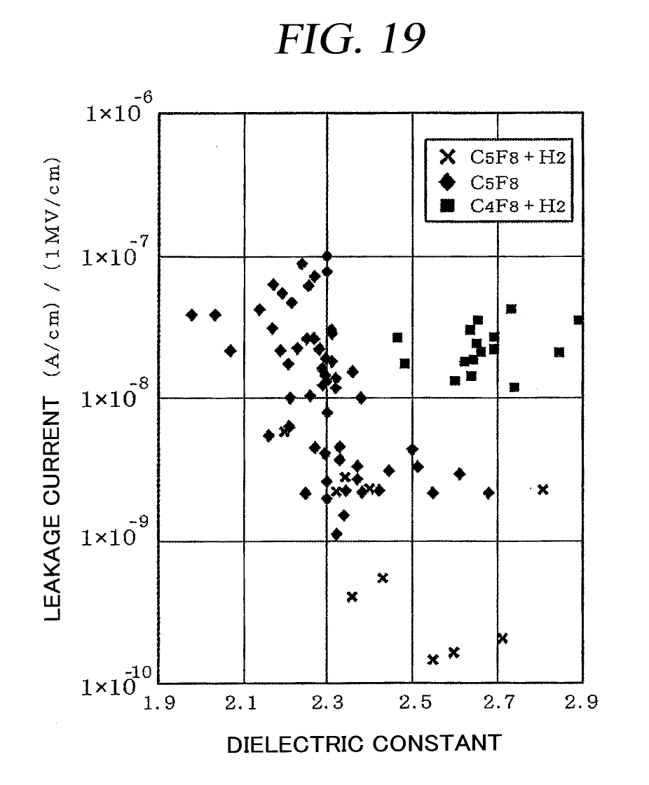

FIG. 19 shows the measurement result, wherein X indicates a case of using the C₅F₈ gas and the hydrogen gas; ♦ indicates a case of using only the C₅F₈ gas; and ▪ indicates a case of using the C₄F₈ gas and the hydrogen gas. In FIG. 19, a horizontal axis represents a dielectric constant, and a vertical axis indicates a leakage current value when an electric field of about 1 MV/cm was applied to the fluorine-containing carbon film. As a result, it is confirmed that when the C₅F₈ gas and the hydrogen gas are used, the leakage current is smaller than that in case of using the C₄F₈ gas and the hydrogen gas, and the dielectric constant can be reduced depending on setting of conditions.

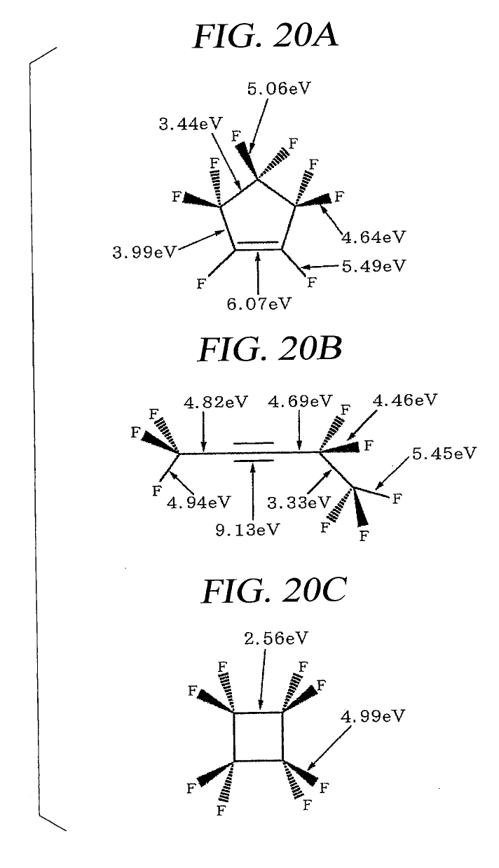

The reason for this is deemed to be as follows. To examine a bond energy of each bond of the C₅F₈ gas and the C₄F₈ gas, a cyclic C₅F₈ gas is shown in FIG. 20A; a straight chain C₅F₈ gas is shown in FIG. 20B; and a C₄F₈ gas is shown in FIG. 20C. A C—C bond energy of the C₄F₈ gas is found to be lower than any bond energy of the C₅F₈ gas. Therefore, the dissociation of the C₄F₈ gas progresses easily in the plasma, and the C₅F₈ is mainly generated. Accordingly, the resultant fluorine-containing carbon film basically has a (—CF₂—)n structure, and this structure remains even if polymerization is facilitated by adding the hydrogen gas.

Meanwhile, in case of converting the C₅F₈ gas into plasma, the excessive dissociation is suppressed as mentioned above, so that the fluorine-containing carbon film is formed while maintaining an original molecular structure thereof. For this reason, it is believed that the fluorine-containing carbon film formed by using the C₅F₈ gas and the hydrogen gas has improved film characteristics such as the leakage characteristic, the dielectric constant, the thermal stability and the like.

### H. Summary

As described above, forming a fluorine-containing carbon film by combining a C₅F₈ gas and a hydrogen gas is very effective in consideration of leakage characteristic, hardness, elasticity, thermal stability and film forming speed. However, since each value of the leakage characteristic, the hardness, the elasticity, the thermal stability and the film forming speed can be varied depending on the amount of the hydrogen gas mixed with the C₅F₈ gas and the dielectric constant slightly increases due to the addition of the hydrogen gas, it is required to attempt to optimize the mixing amount of the hydrogen gas based on these considerations. The inventors of the present invention have found that it is desirable to set the mixing amount of the hydrogen gas such that the flow rate ratio of the hydrogen gas to the C₅F₈ gas ranges from about 20% to 60% when using the fluorine-containing carbon film as an insulating film.

What is claimed is:

1. A film forming method for forming a fluorine-containing carbon film by using active species obtained by activating a C₅F₈ gas and a hydrogen gas.

2. The film forming method of claim 1, wherein the hydrogen gas is mixed with the C₅F₈ gas such that a flow rate ratio of the hydrogen gas to the C₅F₈ gas is about 20% to 60%.

3. The film forming method of claim 1, wherein the C₅F₈ gas is a gas selected from an octafluorocyclopentene gas, an octafluoropentyne gas and an octafluoropentadiene gas.

4. The film forming method of claim 1, wherein the fluorine-containing carbon film is an insulating film included in a semiconductor device.

5. A film forming method comprising:
mounting a substrate to be subjected to a film forming process on a mounting unit in a processing vessel;
introducing a plasma generating gas from an upper portion of the processing vessel;
vacuum-exhausting an inside of the processing vessel from a lower side below the substrate;
introducing a C₅F₈ gas into the processing vessel from between a position corresponding to a height at which the plasma generating gas is introduced and a position corresponding to a height of the substrate;
introducing a hydrogen gas into the processing vessel; and
converting the C₅F₈ gas and the hydrogen gas into a plasma by supplying a microwave into the processing vessel from a planar antenna member installed at the upper portion of the processing vessel to face the mounting table and provided with a number of slits along a circumferential direction.

6. A film forming apparatus comprising:
an airtightly sealed processing vessel including therein a mounting unit for mounting a substrate thereon;
a unit for supplying a C₅F₈ gas into the processing vessel;
a unit for supplying a hydrogen gas into the processing vessel;
a plasma generating unit for supplying an energy to the C₅F₈ gas and the hydrogen gas to convert the gases into a plasma;
a unit for vacuum-evacuating an inside of the processing vessel; and
a control unit for outputting a control instruction to each unit to introduce the C₅F₈ gas and the hydrogen gas into the processing vessel and to convert the gases into the plasma.

7. The film forming apparatus of claim 6, wherein the plasma generating unit includes:
a waveguide for guiding a microwave into the processing vessel; and
a planar antenna member connected to the waveguide, installed to face the mounting unit and provided with a number of slits along a circumferential direction,
wherein the unit for supplying the C₅F₈ gas into the processing vessel introduces the C₅F₈ gas into the processing vessel from between a position corresponding to a height of a unit for supplying a plasma generating gas, which is to be excited by the microwave, into the processing vessel and a position corresponding to a height of the substrate mounted on the mounting unit.

8. The film forming apparatus of claim 6, further comprising:
a flow rate control unit for controlling a flow rate of the C₅F₈ gas and a flow rate of the hydrogen gas supplied into the processing vessel,
wherein the flow rate control unit is controlled by the control unit to mix the hydrogen gas with the C₅F₈ gas such that a flow rate ratio of the hydrogen gas to the C₅F₈ gas becomes about 20% to 60%.

9. The film forming apparatus of claim 6, wherein the C₅F₈ gas is a gas selected from an octafluorocyclopentene gas, an octafluoropentyne gas and an octafluoropentadiene gas.

10. A storage medium for storing therein a computer program executed on a computer and used in a film forming apparatus,
wherein the computer program is composed of steps for executing a film forming method as claimed in claim 1.

11. A semiconductor device comprising an insulating film made of a fluorine-containing carbon film formed by a method as claimed in claim 1.
